(19) United States
(12) Patent Application Publication
(10) Pub. No.: US 2025/0294696 A1
(43) Pub. Date: Sep. 18, 2025

(54) HOUSING COVER FOR ELECTRONIC COMPONENT

(71) Applicant: TOYO DENSO KABUSHIKI KAISHA, TOKYO (JP)

(72) Inventors: Yoshihiko KOIBUCHI, Saitama (JP); Kyoji IOKA, Saitama (JP); Suguru HASHIZUME, Saitama (JP); Koki NOMURA, Saitama (JP)

(73) Assignee: TOYO DENSO KABUSHIKI KAISHA, TOKYO (JP)

(21) Appl. No.: 19/066,567

(22) Filed: Feb. 28, 2025

(30) Foreign Application Priority Data
Mar. 18, 2024 (JP) 2024-042063

(51) Int. Cl. H05K 5/06

(52) U.S. Cl. CPC H05K 5/061

(57) ABSTRACT

A housing cover of the present disclosure is a housing cover for electronic component that closes an opening of a housing main body that houses an electronic component. The housing cover includes a sealing member that closes a gap with the periphery of the opening of the housing main body, at a portion on the reverse side of the housing cover facing the periphery of the opening of the housing main body. In the same positions corresponding to each other on the surface side and the reverse side at least in a portion in the vicinity of the periphery of the housing cover, ribs having the same shapes and sizes on the surface side and the reverse side are formed.

### INCORPORATION BY REFERENCE

This application is based upon and claims the benefit of priority from Japanese patent application No. 2024-042063, filed on Mar. 18, 2024, the disclosure of which is incorporated herein in its entirety by reference.

### TECHNICAL FIELD

The present invention relates to a housing cover used for a housing for an electronic component.

### BACKGROUND ART

As a housing in which an electronic component is housed, there is one described in Patent Literature 1. Patent Literature 1 describes that a housing that houses an electronic component is required to have an electromagnetic wave shielding property, be excellent in heat dissipation characteristic and mechanical strength, and be light-weight, and that a metal member as the main part of the housing is reinforced with a resin member. In addition to this, Patent Literature 1 describes forming resin member ribs on both the surface side and reverse side of the housing in order to inhibit warping.
Patent Literature 1: Japanese Patent Publication No. 7212453

However, further sealability is not considered in the housing described in Patent Literature 1 as described above. That is to say, although Patent Literature 1 describes inhibiting warping, the ribs are asymmetrical on the surface side and the reverse side, and therefore warping may still occur during molding. As a result, there arises a problem that further increase of the sealability of a housing that houses an electronic component cannot be achieved.

### SUMMARY OF THE INVENTION

Accordingly, an object of the present disclosure is to provide a housing cover that can achieve further sealability increase in a housing for an electronic component.

A housing cover for electronic component as an aspect of the present disclosure is a housing cover for electronic component that closes an opening of a housing main body that houses an electronic component. The housing cover includes a sealing member that closes a gap with a periphery of the opening of the housing main body, at a portion on a reverse side of the housing cover facing the periphery of the opening of the housing main body. In same positions corresponding to each other on a surface side and the reverse side at least in a portion in a vicinity of a periphery of the housing cover, ribs having same shapes and sizes on the surface side and the reverse side are formed.

Further, a housing for electronic component as an aspect of the present disclosure includes a housing main body that houses an electronic component, and a housing cover that closes an opening of the housing main body. The housing further includes a sealing member that closes a gap with a periphery of the opening of the housing main body, at a portion on a reverse side of the housing cover facing the periphery of the opening of the housing main body. In same positions corresponding to each other on a surface side and the reverse side at least in a portion in a vicinity of a periphery of the housing cover, ribs having same shapes and sizes on the surface side and the reverse side are formed.

With the configurations as described above, the present disclosure can provide a housing cover that can achieve further sealability increase in a housing for an electronic component.

### BRIEF DESCRIPTION OF DRAWINGS

FIG. 1 is a diagram illustrating an exterior of a housing for electronic component of the present disclosure;

FIG. 2 is a perspective view of a housing cover for electronic component disclosed in FIG. 1 viewed from the surface side;

FIG. 3 is a perspective view of the housing cover for electronic component disclosed in FIG. 1 seen from the reverse side;

FIG. 4 is a cross-section view of part of the housing cover for electronic component disclosed in FIG. 1; and

FIG. 5 is an enlarged view of part of the housing cover for electronic component disclosed in FIG. 1.

### EXAMPLE EMBODIMENT

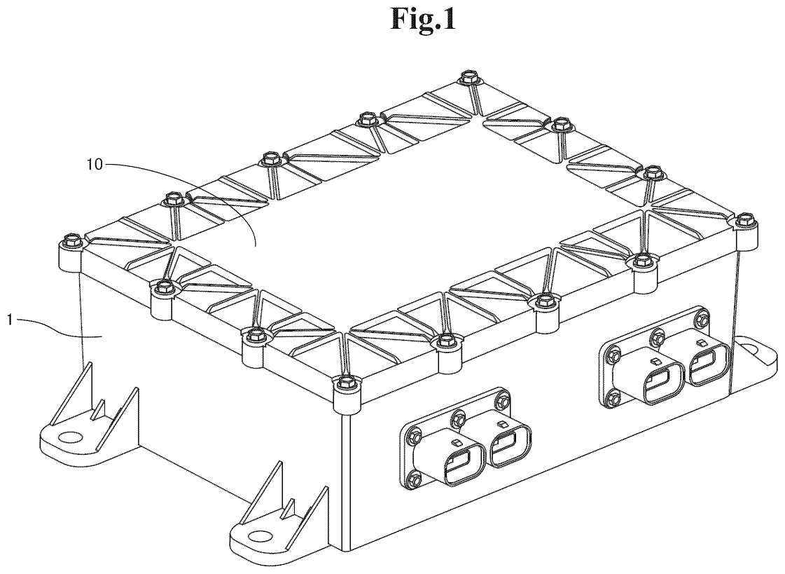

A first example embodiment of the present disclosure will be described with reference to FIGS. 1 to 5.

A housing for electronic component in this example embodiment houses an electronic component and is mounted in a vehicle. The housing includes a housing main body 1 that houses an electronic component, and a housing cover 10 that closes an opening of the housing main body 1. The housing cover 10 will be described in detail below.

The housing cover 10 is configured with a substantially plate-like member that has a substantially rectangular outer shape and has a predetermined thickness in a such a manner as to cover an opening on the upper surface side of the housing main body 1 that is a box body having a substantially rectangular shape as shown in FIG. 1. The housing cover 10 is produced by molding a resin, for example. The outer shapes of the housing main body 1 and the housing cover 10 are not limited to those shown in FIG. 1 and may be any shapes.

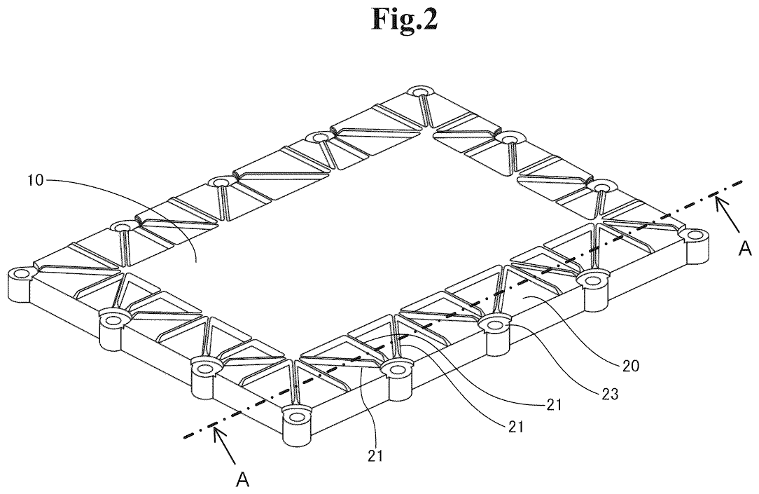

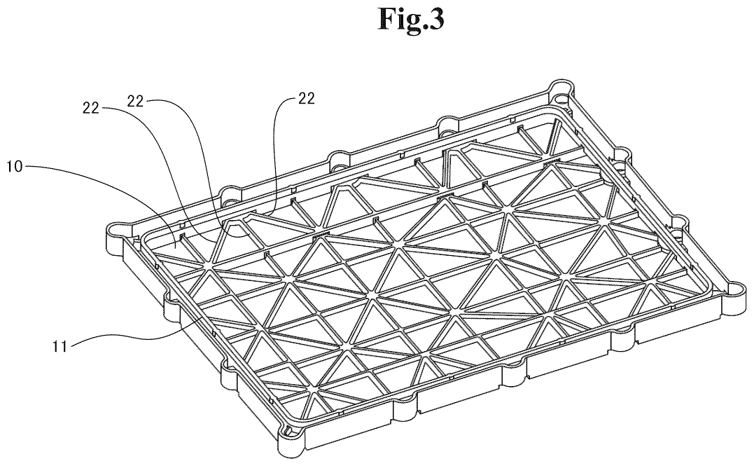

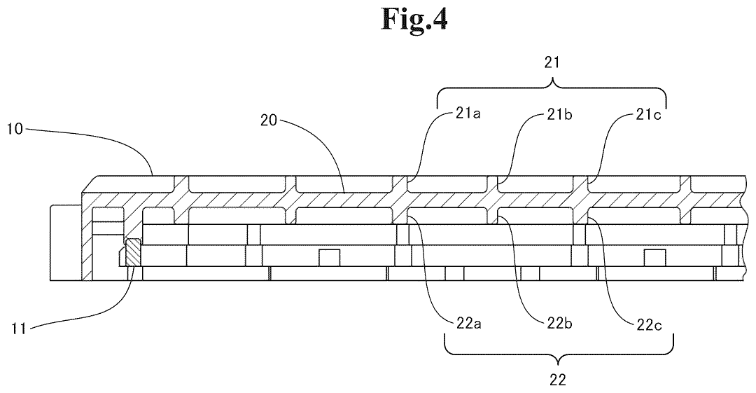

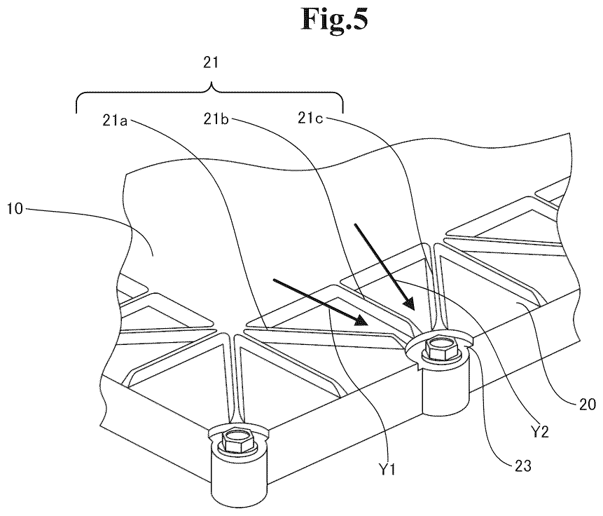

FIG. 2 shows a perspective view of the housing cover 10 seen from the surface side, and FIG. 3 shows a perspective view of the housing cover 10 seen from the reverse side, that is, seen from a side facing the interior of the housing main body 1. FIG. 4 shows a cross-section view of part of line A-A in FIG. 2, and FIG. 5 shows an enlarged view of part of FIG. 2

First, a configuration of the surface side of the housing cover 10 will be described. As shown in FIG. 2, the surface side of the housing cover 10 is formed in a plane shape at a portion in the vicinity of the center, and a portion in the vicinity of the periphery located further to the outer periphery than the vicinity of the center is formed as a stepped part 20 formed in a step shape with a lower height than the surface portion in the vicinity of the center. That is to say, the annular stepped part 20 located in the vicinity of the outer periphery is formed on the surface side of the housing cover 10.

The stepped part 20 formed on the surface side of the housing cover 10 has its surface formed in a plane shape, and a plurality of linear ribs 21 protruding from the surface are formed. That is to say, on the surface side of the housing cover 10, a rib 21 is formed only on the stepped part 20 in the vicinity of the outer periphery. Consequently, deformation such as warping due to heat shrinkage during molding can be inhibited in the stepped part 20 in the vicinity of the outer periphery, and a sealing member 11 provided on the reverse side of the housing cover 10 can be uniformly compressed by sandwiching between the housing cover 10 and the housing main body 1 as will be described later. However, on the surface side of the housing cover 10, the ribs 21 are not necessarily limited to being formed only in the vicinity of the outer periphery, and may be formed at other portions.

The plurality of ribs 21 formed at the stepped part 20 on the surface side of the housing cover 10 are each formed in a linear shape of a predetermined length, and ends thereof are formed to extend toward the periphery. For example, as shown in FIG. 2, each of the ribs 21 is formed in such a manner that one end is located at the planar shape portion in the vicinity of the center and the other end extends toward an edge portion in the vicinity of the periphery. Therefore, the ribs 21 are formed in such a manner that the periphery of the housing cover 10 is not surrounded by the ribs themselves. Furthermore, since the ribs 21 are formed at predetermined spaces from each other, the space between the ribs forms an opening passage (opening portion) that opens toward the periphery, and a flowing water path can be secured by the opening passage as will be described later. At this time, the space between the other ends separated from each other of the ribs 21 located in adjacent to each other forms the opening end of the opening passage, and flowing water paths can be secured in the peripheral direction at a plurality of locations.

FIG. 5 shows an enlarged view of the vicinity of the periphery on the surface side of the housing cover 10. In this view, the three ribs 21 are denoted by reference numerals 21a, 21b, and 21c, respectively. As shown in this view, an opening passage indicated by an arrow Y1 is formed between the mutually adjacent ribs 21a and 21b, and an end thereof is an opening end that opens toward the periphery. At this time, the mutually adjacent ribs 21a and 21b are formed in such a manner that the space between the ribs narrows as it heads in the peripheral direction. That is to say, the opening passage indicated by the arrow Y1 is formed to gradually narrow as it heads toward the periphery. Likewise, between the mutually adjacent ribs 21b and 21c, an opening passage is formed in which the space gradually narrows toward the periphery as indicated by an arrow Y2, and an end thereof is an opening end that opens toward the periphery.

Further, as shown in FIG. 5, on the surface side of the housing cover 10, a second stepped part 23 formed even lower in height than the surface of the stepped part 20 is formed on the surface located further to the periphery than the opening ends of the opening passages Y1 and Y2 formed at the space between the ribs described above. In this example embodiment, the second stepped parts 23 are formed in a plurality of locations on the edge around the housing cover 10 and is formed in a circular shape that is even lower than the surface of the stepped part 20. The sealing member 11 provided on the reverse side of the housing cover 10 to be described later is placed more internally than the second stepped part 23, so that compression is uniformly applied at the time of assembly into the sealing member 11 and sealability can be secured. However, the second stepped part 23 may be formed in any portion, and may have any shape.

Since the surface side of the housing cover 10 is formed as described above, it is possible to achieve increase of the drainage property. That is to say, since the surface side of the housing cover 10 has a plane shape in the vicinity of the center and has the stepped part 20 like a step formed lower in height in the vicinity of the periphery, the water located in the vicinity of the center flows toward the lower-height stepped part 20 on the periphery. At this time, on the stepped part 20, opening passages Y1 and Y2 opening toward the periphery are formed by the spaces between the plurality of ribs 21, and the water flowing into the stepped part 20 flows in the opening passages Y1 and Y2. In particular, since the opening passages Y1 and Y2 are narrower as they head toward the periphery, the outflow of the water to the periphery is facilitated. Moreover, since the second stepped part 23 formed still lower in height is formed in the vicinity of the opening end of the opening passage Y1, Y2, the outflow of the water to the periphery is facilitated.

Next, a configuration of the reverse side of the housing cover 10 will be described. As shown in FIG. 3, a rib 22 is formed also on the reverse side of the housing cover 10. To be specific, a plurality of ribs 22 are formed on the entire surface on the reverse side of the housing cover 10. That is to say, on the reverse side of the housing cover 10, a plurality of linear ribs 22 protruding from the reverse side are formed at a portion corresponding to the vicinity of the center of the surface side and a portion corresponding to the stepped part 20 in the vicinity of the periphery of the surface side. The ribs 22 on the reverse side of the housing cover 10 may not be formed in the vicinity of the center, and may be formed only in the vicinity of the periphery in the same manner as the surface side.

Then, among the ribs 22 on the reverse side of the housing cover 10, the ribs 22 in the vicinity of the outer periphery are formed in the same shape and size at the same positions as the ribs 21 formed on the surface side. That is to say, at a portion in the vicinity of the periphery of the housing cover 10 and corresponding to the stepped part 20 on the surface side, the ribs 21 and 22 having the same shape and size on the surface side and the reverse side are formed in the same positions corresponding to each other on the surface side and the reverse side.

For example, as shown in a cross-section view of FIG. 4, a pair of linear ribs 21a and 22a formed in mutually corresponding positions on the surface side and the reverse side are formed in the same length, width, protrusion height, and formed position, respectively. Likewise, all pairs of ribs formed in the vicinity of the periphery of the housing cover 10 are formed in the same length, width, protrusion height, and formed position on the surface side and the reverse side, such as a pair of ribs 21b and 22b and a pair of ribs 21c and 22c shown in FIG. 4

Further, as shown in FIG. 3, the sealing member 11 is provided on the periphery of the reverse side of the housing cover 10. To be specific, the sealing member 11 is formed in a substantially rectangular annular shape corresponding to the outer periphery shape of the housing cover 10, sandwiched between the housing cover 10 and the housing main body 1 in the vicinity of the outer periphery edge, and uniformly compressed and placed. Consequently, the housing cover 10 is assembled into the housing main body 1, so that the sealing member 11 is placed facing the periphery of the opening of the housing main body 1, that is, the upper end of the side wall of the housing main body 1, and functions to close the gap with the periphery of the opening of the housing main body 1.

As described above, the housing cover 10 in this example embodiment has the ribs 21 and 22 formed in the same shapes and the same sizes at the same positions on the periphery on the surface side and the reverse side. Consequently, warping that may occur during molding of the housing cover 10 can be inhibited more effectively. Then, when the housing cover 10 is attached to the opening of the housing main body 1, the sealing member 11 hermetically seals the opening of the housing main body 1, and the warping of the housing cover 10 is further inhibited, so that it is possible to achieve increase of the sealability.

Furthermore, as described above, since the front side of the housing cover 10 is configured in such a manner that the drainage property increases, it is possible to achieve further increase of the sealability.

### SUPPLEMENTARY NOTES

The whole or part of the example embodiments disclosed above can be described as the following supplementary notes. Below, the overview of a housing cover in the present invention will be described. However, the present invention is not limited to the following configurations.

### Supplementary Note 1

A housing cover for electronic component that closes an opening of a housing main body that houses an electronic component, the housing cover comprising
a sealing member that closes a gap with a periphery of the opening of the housing main body, at a portion on a reverse side of the housing cover facing the periphery of the opening of the housing main body,
wherein in same positions corresponding to each other on a surface side and the reverse side at least in a portion in a vicinity of a periphery of the housing cover, ribs having same shapes and sizes on the surface side and the reverse side are formed.

### Supplementary Note 2

The housing cover according to supplementary note 1, wherein
the ribs formed in the same positions on the surface side and the reverse side are formed only in the portion in the vicinity of the periphery of the housing cover.

### Supplementary Note 3

The housing cover according to supplementary note 2, wherein
a face in the portion in the vicinity of the periphery on the surface side of the housing cover where the ribs are formed in the same positions on the surface side and the reverse side is lower in height than another portion and is formed in a stepped shape.

### Supplementary Note 4

The housing cover according to supplementary note 3, wherein
the ribs formed on the surface side of the housing cover are formed to have an opening portion in such a manner so as not to surround the housing cover along a direction of the periphery.

### Supplementary Note 5

The housing cover according to supplementary note 4, wherein
the ribs formed on the surface side of the housing cover are formed to have predetermined lengths, the ribs are formed to be separated from each other, and a space between the ribs forms the opening portion.

### Supplementary Note 6

The housing cover according to supplementary note 5, wherein
the ribs formed on the surface side of the housing cover have ends formed toward the periphery, and a space between the ends of the ribs formed in adjacent forms the opening portion.

### Supplementary Note 7

The housing cover according to supplementary note 6, wherein
the ribs formed on the surface side of the housing cover are formed in such a manner that the space between the ribs formed in adjacent narrows as it heads toward the periphery.

### Supplementary Note 8

The housing cover according to supplementary note 6, wherein
a face located even closer to the periphery than the opening portion on the surface side of the housing cover is formed even lower in height than the face formed in the stepped shape.

### Supplementary Note 9

A housing comprising:
a housing main body that houses an electronic component; and
a housing cover that closes an opening of the housing main body,
the housing further comprising
a sealing member that closes a gap with a periphery of the opening of the housing main body, at a portion on a reverse side of the housing cover facing the periphery of the opening of the housing main body,
wherein in same positions corresponding to each other on a surface side and the reverse side at least in a portion in a vicinity of a periphery of the housing cover, ribs having same shapes and sizes on the surface side and the reverse side are formed.

Although the present invention has been described above with reference to the above-described example embodiments, the present invention is not limited to the example embodiments described above. The configuration and details of the present invention can be changed in various manners that can be understood by those skilled in the art within the scope of the present invention.

### DESCRIPTION OF REFERENCE NUMERALS

1 housing main body
10 housing cover
11 sealing member
20 stepped part
21, 22 rib
23 second stepped part

1. A housing cover for electronic component that closes an opening of a housing main body that houses an electronic component, the housing cover comprising
a sealing member that closes a gap with a periphery of the opening of the housing main body, at a portion on a reverse side of the housing cover facing the periphery of the opening of the housing main body,
wherein in same positions corresponding to each other on a surface side and the reverse side at least in a portion in a vicinity of a periphery of the housing cover, ribs having same shapes and sizes on the surface side and the reverse side are formed.

2. The housing cover according to claim 1, wherein
the ribs formed in the same positions on the surface side and the reverse side are formed only in the portion in the vicinity of the periphery of the housing cover.

3. The housing cover according to claim 2, wherein
a face in the portion in the vicinity of the periphery on the surface side of the housing cover where the ribs are formed in the same positions on the surface side and the reverse side is lower in height than another portion and is formed in a stepped shape.

4. The housing cover according to claim 3, wherein
the ribs formed on the surface side of the housing cover are formed to have an opening portion in such a manner so as not to surround the housing cover along a direction of the periphery.

5. The housing cover according to claim 4, wherein
the ribs formed on the surface side of the housing cover are formed to have predetermined lengths, the ribs are formed to be separated from each other, and a space between the ribs forms the opening portion.

6. The housing cover according to claim 5, wherein
the ribs formed on the surface side of the housing cover have ends formed toward the periphery, and a space between the ends of the ribs formed in adjacent forms the opening portion.

7. The housing cover according to claim 6, wherein
the ribs formed on the surface side of the housing cover are formed in such a manner that the space between the ribs formed in adjacent narrows as it heads toward the periphery.

8. The housing cover according to claim 6, wherein
a face located even closer to the periphery than the opening portion on the surface side of the housing cover is formed even lower in height than the face formed in the stepped shape.

9. A housing comprising:
a housing main body that houses an electronic component; and
a housing cover that closes an opening of the housing main body,
the housing further comprising
a sealing member that closes a gap with a periphery of the opening of the housing main body, at a portion on a reverse side of the housing cover facing the periphery of the opening of the housing main body,
wherein in same positions corresponding to each other on a surface side and the reverse side at least in a portion in a vicinity of a periphery of the housing cover, ribs having same shapes and sizes on the surface side and the reverse side are formed.
